(19) United States
(12) Patent Application Publication
(10) Pub. No.: US 2012/0181600 A1
(43) Pub. Date: Jul. 19, 2012

(54) SONOS FLASH MEMORY DEVICE

(76) Inventor: Masahiko HIGASHI, Fukushima (JP)

(21) Appl. No.: 13/275,989

(22) Filed: Oct. 18, 2011

Related U.S. Application Data
(63) Continuation-in-part of application No. 12/193,266, filed on Aug. 18, 2008, now Pat. No. 8,076,206.

(30) Foreign Application Priority Data
Aug. 17, 2007 (JP) 2007-213001

(51) Int. Cl. H01L 29/792

(52) U.S. Cl. 257/324; 257/E29.309

(57) ABSTRACT

A semiconductor device fabricated by forming a dummy layer on a semiconductor substrate, forming a groove in the semiconductor substrate while using the dummy layer as a mask, forming a tunnel insulating film and a trap layer to cover an inner surface of the groove and the dummy layer, eliminating the trap layer formed above the upper surface and at the sides of the dummy layer, and forming a top insulating film to cover a remaining trap layer and the exposed tunnel insulating film.

### CLAIM OF PRIORITY

This application is a Continuation-In-Part of U.S. patent application Ser. No. 12/193,266, filed Aug. 18, 2008, itself also claiming priority to corresponding Japanese patent application 2007-213001 filed on Aug. 17, 2007. Both references are incorporated herein in their entireties by reference.

### TECHNICAL FIELD OF THE INVENTION

This invention relates to a method for manufacturing a semiconductor device. More particularly, this invention relates to a method for manufacturing a semiconductor device having a trap layer on a side surface of a groove formed in a semiconductor substrate.

### BACKGROUND OF THE INVENTION

Recently, the usage of non-volatile memory comprising a semiconductor device capable of rewriting data and retaining data stored therein even while the device is un-powered has become increasingly popular. Flash memory is one example of non-volatile memory. A typical flash memory is provided with a transistor which operates as a memory cell and includes a floating gate or an insulating film called a charge storage layer for accumulating electrons used to store data. Flash memory with a SONOS (Silicon Oxide Nitride Oxide Silicon) structure for accumulating the electrons in a trap layer of an ONO (Oxide Nitride Oxide) film has been introduced as a flash memory using an insulating film as the charge storage layer.

A technique for forming the ONO film on the side surface of a groove formed in the semiconductor substrate has been developed to miniaturize the memory cell. PCT International Application No. 2005-525695 discloses a method for manufacturing the flash memory having the aforementioned groove as described below. According to PCT International Application No. 2005-525695, the trench is formed in the semiconductor substrate while using the auxiliary layer formed of the nitride film as a mask. Thus, the ONO film is formed on the wall of the trench. The gate electrode (formed of polysilicon) is formed in the trench. The auxiliary layer is eliminated to form the source/drain region in the semiconductor substrate while using the gate electrode as the mask. The insulating film is then formed on the source/drain region and the word line is formed on the insulating layer. The source/drain region may be formed after forming the ONO film. The insulating layer may be used to electrically separate the source/drain region from the word line.

However, according to this technique, the trap layer constituting the ONO film is eroded while eliminating a dummy layer used as a mask to form the groove. The level of the erosion varies depending on the individual wafer or the manufacturing lot. Occasionally, the trap layer may become sufficiently eroded so as to interfere with the stable operation of the flash memory.

### SUMMARY OF THE INVENTION

It is an object of the invention to suppress erosion of the trap layer upon elimination of the dummy layer.

According to an aspect of the present invention, there is provided a method for manufacturing a semiconductor device comprising” forming a dummy layer on a semiconductor substrate, forming a groove in the semiconductor substrate while using the dummy layer as a mask, forming a tunnel insulating film and a trap layer to cover an inner surface of the groove and the dummy layer, eliminating the trap layer formed above an upper surface, and at sides of the dummy layer, and forming a top insulating film to cover a remaining trap layer and an exposed tunnel insulating film. In the method, the trap layer is covered with the top insulating film so as to suppress erosion of the trap layer.

In one embodiment, eliminating the trap layer may comprise forming a bury layer in the groove to expose the trap layer at the sides of the dummy layer, and eliminating the trap layer while using the bury layer as a mask. This makes it possible to eliminate the trap layer formed above the upper surface and at sides of the dummy layer.

In another embodiment, forming a bury layer may comprise forming a layer to be formed as the bury layer to fill the groove and to cover the trap layer, and eliminating the layer to be formed as the bury layer to expose at least the trap layer at the sides of the dummy layer. This makes it possible to form the bury layer in the groove so as to expose the trap layer at the sides of the dummy layer.

In alternate embodiments, the method may further comprise eliminating the dummy layer, and forming a bit line in the semiconductor substrate between the grooves where the dummy layer has been eliminated. This makes it possible to form the bit line after forming the top insulating film.

In still further embodiments, the method may also comprise forming a gate electrode buried in the groove on the top insulating film. Forming the bit line may, for example, comprise performing an ion implantation to the semiconductor substrate while using the gate electrode as a mask.

In one embodiment, forming the gate electrode may comprise forming a layer to be formed as a gate electrode to fill the groove and to cover the top insulating film, and polishing the layer to be formed as the gate electrode to be flush with the dummy layer.

In alternate embodiments, the method may further comprise forming an insulating layer on the bit line to expose an upper surface of the gate electrode, and forming a word line which is coupled to the gate electrode and intersects with the bit line in an extension direction thereof on the insulating layer. In one embodiment, the word line is electrically coupled with the gate electrode, and is separated from the bit line via the insulating layer.

The method may also comprise forming a metal silicide layer on the bit line between the grooves where the dummy layer has been eliminated. This makes it possible to reduce the bit line resistance.

According to one embodiment, the same material may be used for forming the dummy layer and the trap layer, for example, a silicon nitride may be used for forming the dummy layer and the trap layer.

In various embodiments of the aforementioned method, the trap layer is covered with the top insulating film so as to suppress erosion of the trap layer.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 is a top view of an exemplary flash memory in accordance with various embodiments of the present invention;

FIGS. 2(a) to 2(c) are sectional views showing the formation of a dummy layer in a conventional process for manufacturing an exemplary flash memory;

FIGS. 3(a) and 3(b) are sectional views showing the elimination of a dummy layer in a conventional process for manufacturing a flash memory;

FIGS. 4(a) and 4(b) are sectional views showing the formation of a word-line-forming layer in a conventional process for manufacturing a flash memory;

FIGS. 5(a) and 5(b) are sectional views showing the formation of an interlayer insulating film formed on a word line in a conventional process for manufacturing a flash memory in accordance with various embodiments;

FIGS. 6(a) to 6(c) are sectional views showing the formation of a dummy layer on a p-type silicon semiconductor substrate in a process for manufacturing a flash memory in accordance with various embodiments;

FIGS. 7(a) to 7(c) are sectional views showing the elimination of a bury-layer-forming layer in a process for manufacturing an exemplary flash memory in accordance with various embodiments;

FIGS. 8(a) to 8(c) are sectional views showing the formation of a gate-electrode-forming layer in a process for manufacturing an exemplary flash memory in accordance with various embodiments;

FIGS. 9(a) and 9(b) are sectional views showing an arsenic ion implantation in an exposed semiconductor substrate in a process for manufacturing an exemplary flash memory in accordance with various embodiments;

FIGS. 10(a) and 10(b) are sectional views showing the formation of a word-line-forming layer on the surfaces of a gate electrode and the insulating layer in a process for manufacturing an exemplary flash memory in accordance with various embodiments;

FIGS. 11(a) and 11(b) are sectional views showing the formation of an interlayer insulating film on a word line and inside a groove in a process for manufacturing an exemplary flash memory in accordance with various embodiments;

FIG. 12 is a sectional view showing the formation of a metal layer on the inner surface of a recess portion in a process for manufacturing an exemplary flash memory in accordance with various embodiments;

FIGS. 13(a) and 13(b) are sectional views showing the completion of a process for manufacturing the flash memory according to various embodiments;

FIG. 14 depicts a block diagram of an exemplary portable telephone, upon which various embodiments can be implemented;

FIG. 15 depicts a block diagram of an exemplary computing device, upon which various embodiments can be implemented; and

FIG. 16 depicts an exemplary portable multimedia device, or media player, upon which various embodiments can be implemented.

### DETAILED DESCRIPTION

Reference will now be made in detail to several embodiments. While the subject matter will be described in conjunction with the alternative embodiments, it will be understood that they are not intended to limit the claimed subject matter to these embodiments. On the contrary, the claimed subject matter is intended to cover alternative, modifications, and equivalents, which may be included within the spirit and scope of the claimed subject matter as defined by the appended claims.

Furthermore, in the following detailed description, numerous specific details are set forth in order to provide a thorough understanding of the claimed subject matter. However, it will be recognized by one skilled in the art that embodiments may be practiced without these specific details or with equivalents thereof. In other instances, well-known methods, procedures, and components, have not been described in detail as not to unnecessarily obscure aspects and features of the subject matter.

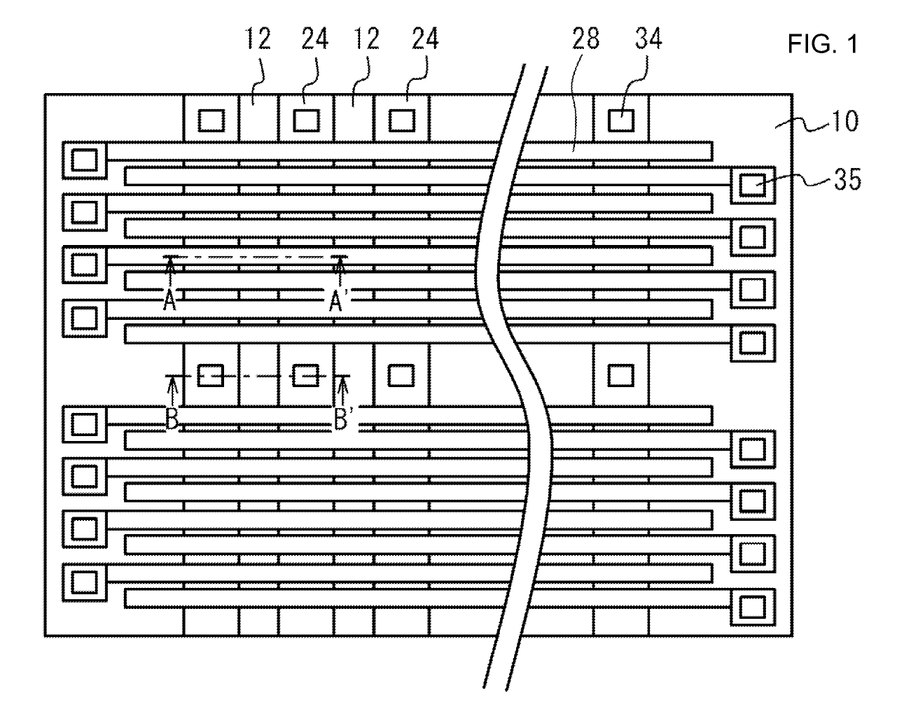

FIG. 1 is a top view of an exemplary flash memory in accordance with various embodiments of the present invention. A plurality of bit lines 24 are formed on a semiconductor substrate 10, and grooves 12 are provided between the adjacent bit lines 24. A plurality of word lines 28 are arranged so as to intersect with the bit lines 24. The bit lines 24 and the word lines 28 are coupled to plug metals 34 and 35, respectively. The plug metals 34 and 35 are further coupled to the wiring layers (not shown).

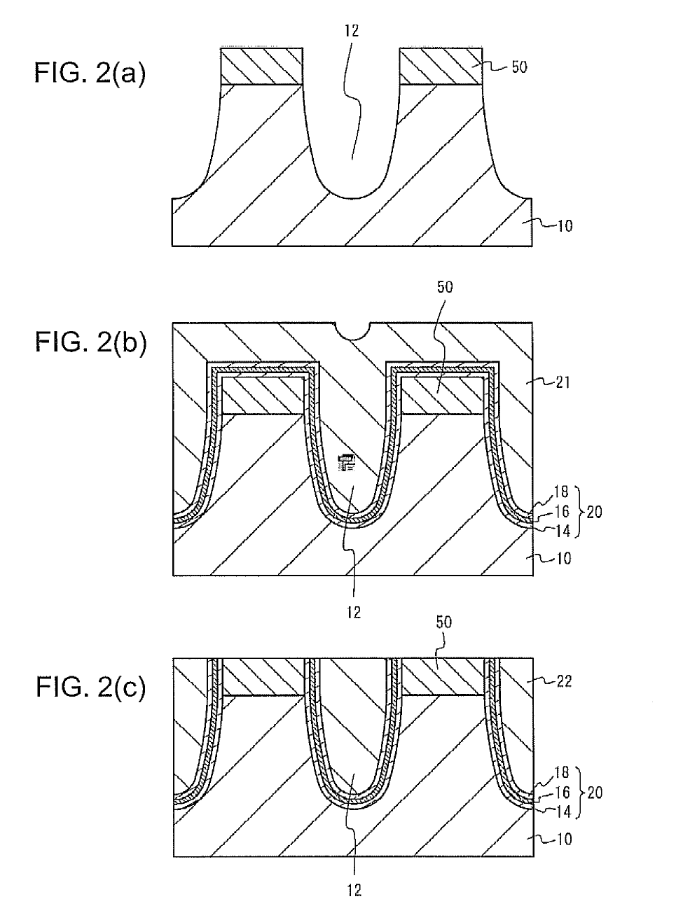

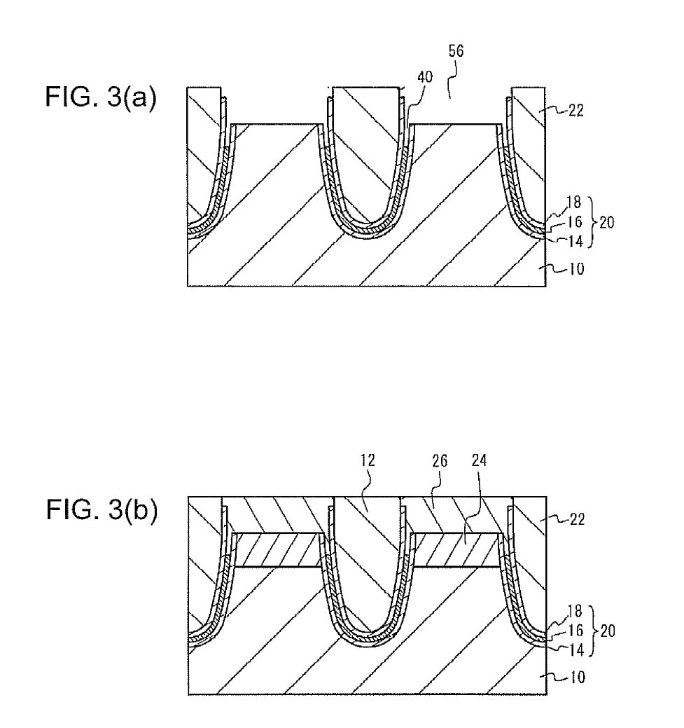

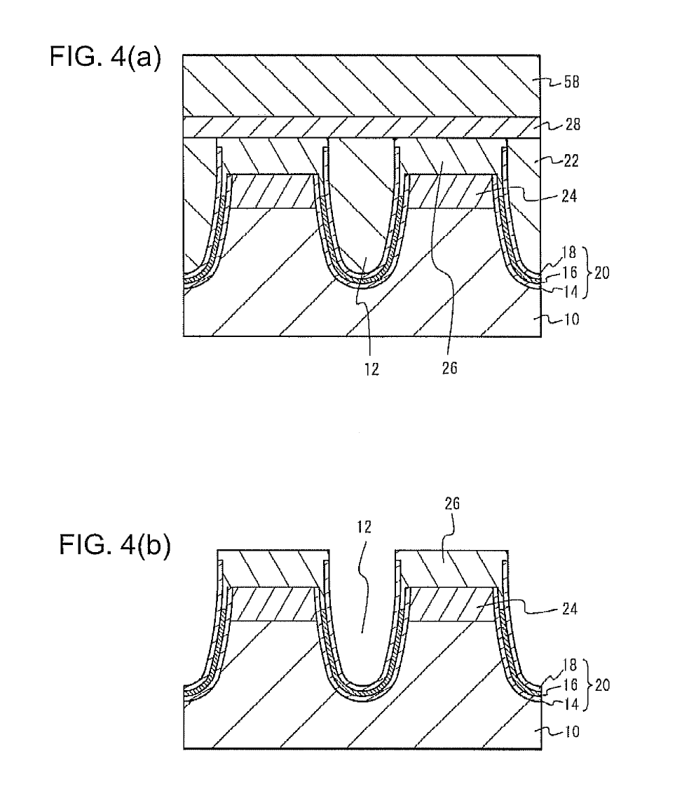

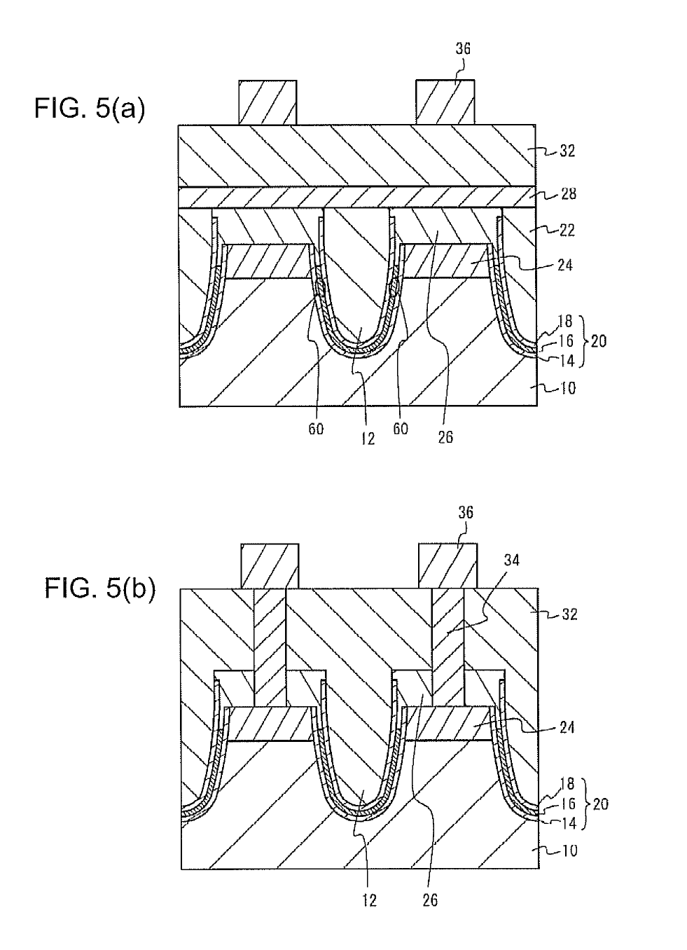

The method for manufacturing the exemplary flash memory according to FIG. 1 will be described referring to FIGS. 2(a) to 4(c). FIGS. 2(a) to 3(b) correspond to sectional views taken along lines A-A′ and B-B′ shown in FIG. 1, respectively. FIGS. 4(a) and 5(a) correspond to sectional views taken along line A-A′ shown in FIG. 1, and FIGS. 4(b) and 5(b) correspond to sectional views taken along line B-B′ shown in FIG. 1, respectively.

Referring to FIG. 2(a), a dummy layer 50 including a patterned silicon nitride film is formed on the semiconductor substrate 10. The semiconductor substrate 10 is etched while using the dummy layer 50 as a mask to form the groove 12. Referring to FIG. 2(b), a tunnel insulating film 14 including a silicon oxide film, a trap layer 16 including a silicon nitride film, and a top insulating film 18 including the silicon oxide film are formed to cover the inner surface of the groove 12 and the dummy layer 50. The tunnel insulating film 14, the trap layer 16 and the top insulating film 18 constitute an ONO film 20. A gate-electrode-forming layer 21 is formed to cover the ONO film 20 and to fill the groove 12. Referring to FIG. 2(c), the gate-electrode-forming layer 21 is polished until the upper surface of the dummy layer 50 is exposed. At this time, the dummy layer 50 serves as a stopper of the polishing.

Referring to FIG. 3(a), the phosphoric acid is used to eliminate the dummy layer 50. As a result, a recess portion 56 is formed in a portion where the dummy layer 50 is eliminated. Referring to FIG. 3(b), the semiconductor substrate 10 as the bottom surface of the recess portion 56 is ion implanted to form the bit line 24. The recess portion 56 is filled to form an insulating layer 26.

Referring to FIGS. 4(a) and 4(b), a word-line-forming layer (not shown) is formed on the entire surfaces of a gate electrode 22 and the insulating layer 26. A patterned photoresist 58 is formed on the word-line-forming layer. The word line 28 and the gate electrode 22 are eliminated while using the photoresist 58 as the mask. As a result, the word line 28 which intersects with the bit line 24 is formed as shown by the cross-section along line A-A′ of FIG. 4(a). The word line 28 is electrically in contact with the gate electrode 22, and is electrically separated from the bit line 24 via the insulating layer 26. The word line 28 and the gate electrode 22 are eliminated as shown by the cross-section along line B-B′ shown in FIG. 4(b).

Referring to FIG. 5(a), an interlayer insulating film 32 is formed on the word line 28, and referring to FIG. 5(b), it is formed in the groove 12 and on the insulating layer 26 after eliminating the photoresist 58. The plug metal 34 coupled to the bit line 24 is formed in the interlayer insulating film 32. A wiring layer 36 is formed that is coupled to the plug metal 34 and extends above the bit line 24 in the same direction thereof. The wiring layer is further layered to complete production of the flash memory.

Referring to FIG. 3(a), in the method according to FIG. 1, the trap layer 16 formed of the silicon nitride film is eroded while eliminating the dummy layer 50 including the silicon nitride film as indicated by a reference numeral 40.

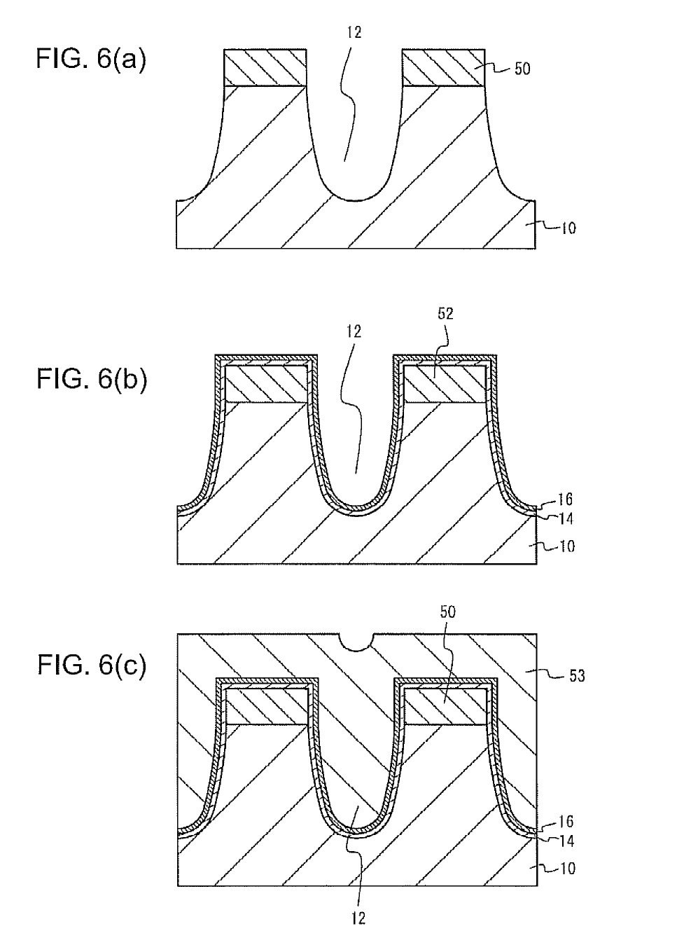

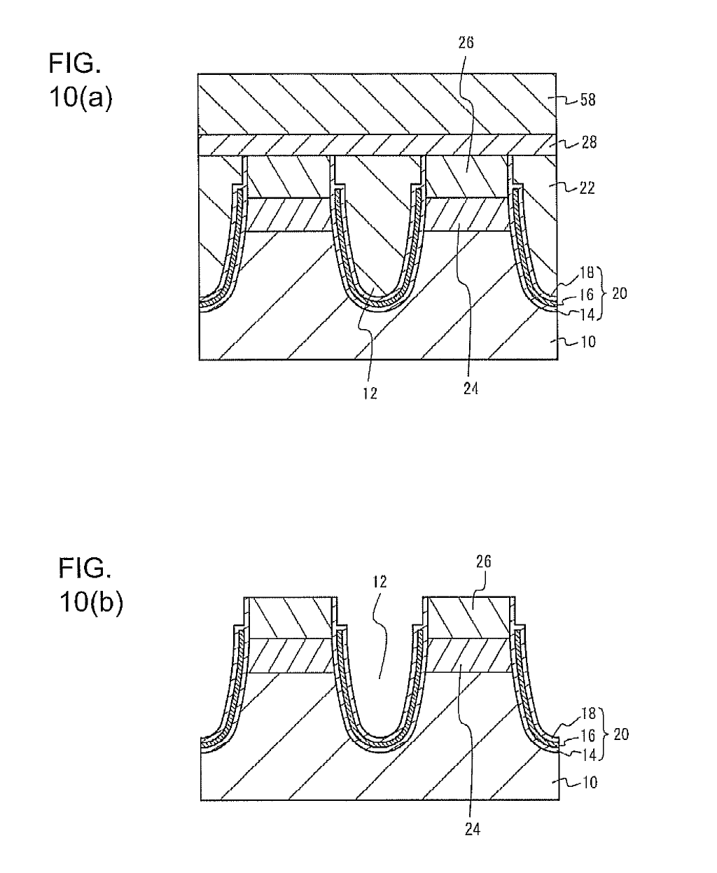

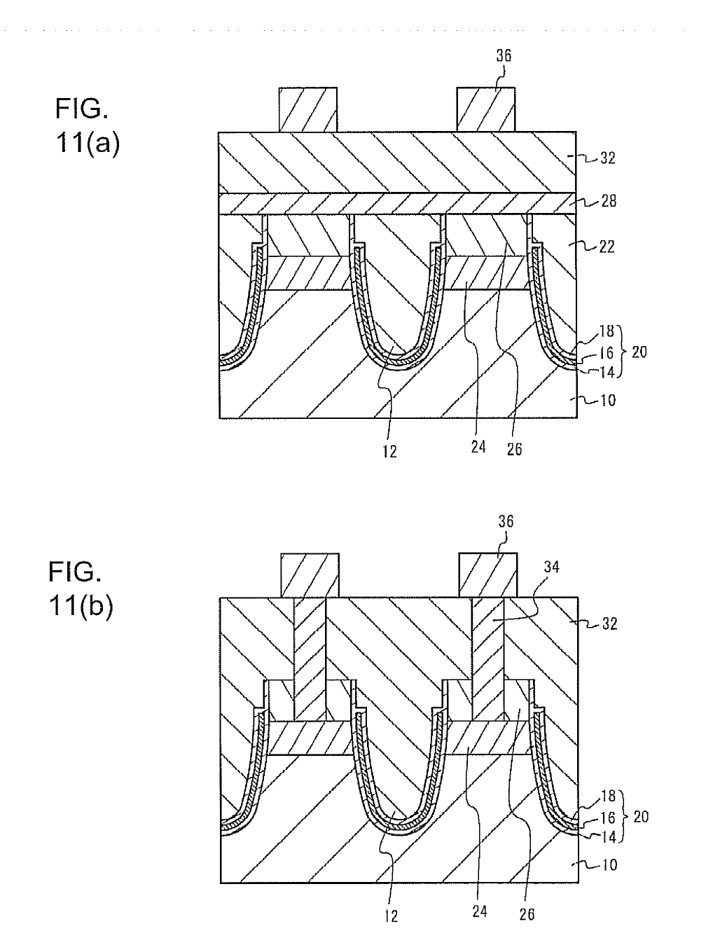

Referring to FIGS. 6(a) to 11(b, a method for manufacturing a flash memory according to one embodiment will be described. FIGS. 6(a) to 9(b) correspond to sectional views taken along lines A-A′ and B-B′ as shown in FIG. 1, respectively. FIGS. 10(a) and 11(a) correspond to sectional views taken along line A-A′ as shown in FIG. 1. FIGS. 10(b) and 11(b) correspond to sectional views taken along line B-B′ as shown in FIG. 1.

Referring to FIG. 6(a), a dummy layer 50 including a patterned silicon nitride film is formed on a p-type silicon semiconductor substrate (or p-type region inside the semiconductor substrate) 10. The dummy layer 50 is formed through a plasma CVD (Chemical Vapor Deposition) process and has the thickness ranging from 100 nm to 200 nm, for example. The semiconductor substrate 10 is etched while using the dummy layer 50 as a mask to form a groove 12 with a depth ranging from 100 nm to 200 nm, for example. Referring to FIG. 6(b), a tunnel insulating film 14 including the silicon oxide film is formed through the thermal oxidation process so as to cover the inner surface of the groove 12 and the outer surface of the dummy layer 50, and a trap layer 16 including the silicon nitride film is formed thereon through the plasma CVD process. Referring to FIG. 6(c), a bury-layer-forming layer 53 including the resist or the resin is formed to fill the groove 12 and to cover the trap layer 16.

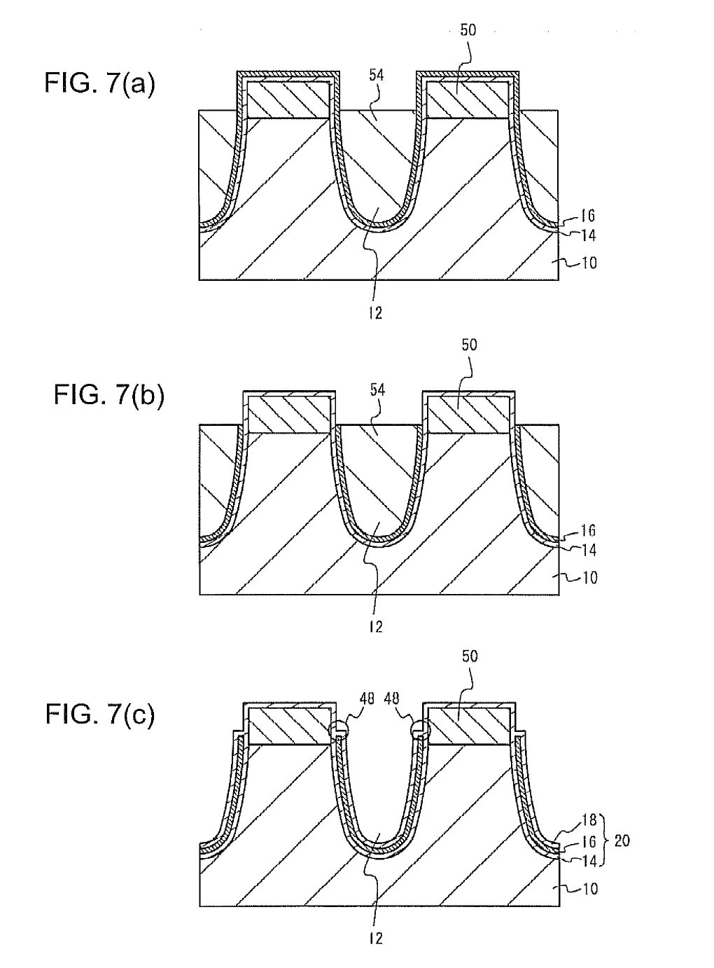

Referring to FIG. 7(a), the bury-layer-forming layer 53 is eliminated by ashing or etching so that the trap layer 16 formed above the upper surface and at the sides of the dummy layer 50 is exposed. The trap layer 16 above the upper surface and at the sides of the dummy layer 50 is exposed from a bury layer 54. The range of the trap layer 16 exposed from the bury layer 54 corresponds to that of the trap layer 16 to be eliminated. So the trap layer 16 formed at the sides of the dummy layer 50 may be partially or completely exposed. Referring to FIG. 7(b), the trap layer 16 is eliminated while using the bury layer 54 as the mask. The trap layer 16 formed above the upper surface and at the sides of the dummy layer 50 may be eliminated. Referring to FIG. 7(c), the bury layer 54 is eliminated, and a top insulating film 18 including the silicon oxide film is formed through the thermal oxidation process so as to cover the remaining trap layer 16 and the exposed tunnel insulating film 14. An ONO film 20 formed of the tunnel insulating film 14, the trap layer 16 and the top insulating film 18 is formed on the side surface of the groove 12.

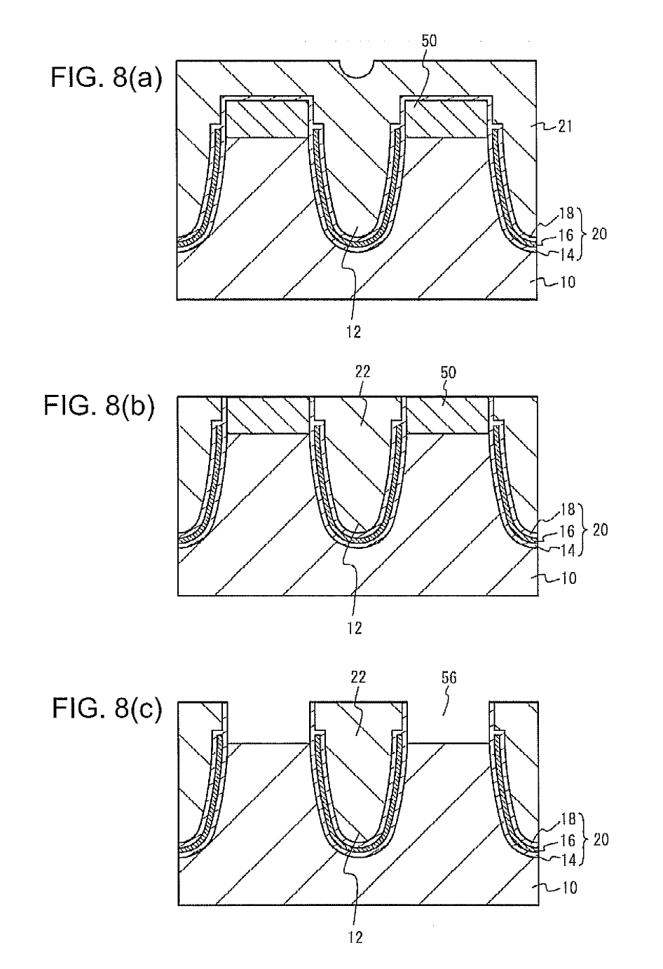

Referring to FIG. 8(a), a gate-electrode-forming layer 21 formed of polysilicon is produced through the CVD process so as to fill the groove 12 and to cover the top insulating film 18. Referring to FIG. 8(b), the gate-electrode-forming layer 21 is polished through the CMP (Chemical Mechanical Polish) process to be flush with the dummy layer 50. As the operation for polishing the silicon nitride film takes longer time compared with the operation for polishing the polysilicon film or the silicon oxide film, the dummy layer 50 functions as a stopper of the operation for polishing the gate-electrode-forming layer 21. Referring to FIG. 8(c), the dummy layer 50 is etched using a phosphoric acid. The space generated by eliminating the dummy layer 50 becomes a recess portion 56. The surface of the semiconductor substrate 10 is exposed as the bottom surface of the recess portion 56.

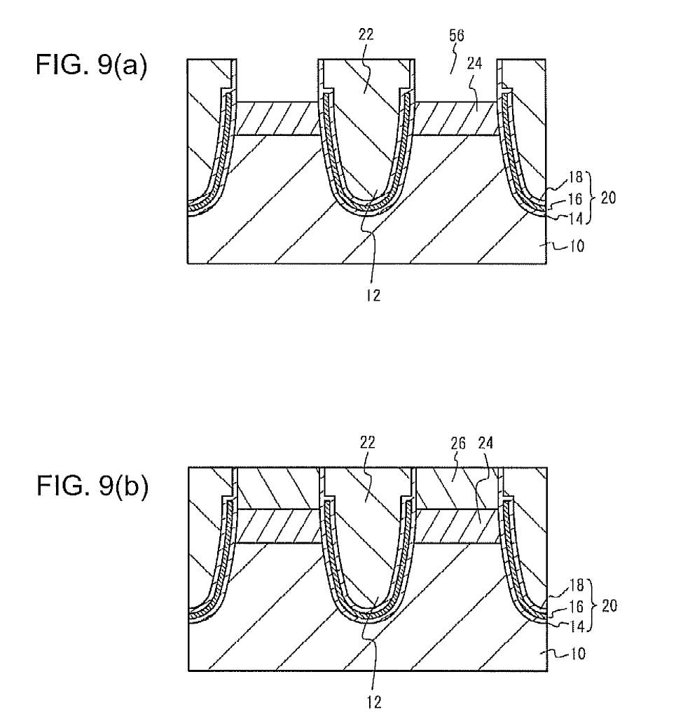

Referring to FIG. 9(a), the exposed semiconductor substrate 10 is subjected to an arsenic (As) ion implantation such that a bit line 24 is formed on the semiconductor substrate 10 between grooves 12 where the dummy layer 50 is eliminated. Referring to FIG. 9(b), an insulating layer 26 including the silicon oxide is formed to fill the recess portion 56. The insulating layer 26 is polished using a CMP process so as to be selectively formed in the recess portion 56.

Referring to FIGS. 10(a) and 10(b), a word-line-forming layer (not shown) including a polysilicon layer is formed on the surfaces of the gate electrode 22 and the insulating layer 26 using the CVD process. A patterned photoresist 58 is further formed on the word-line-forming layer. The word line 28 and the gate electrode 22 are eliminated while using the photoresist 58 as the mask. Referring to FIG. 10(a), the sectional view taken along line A-A′, the word line 28 which intersects with the bit line 24 is formed. The word line 28 is electrically in contact with the gate electrode 22, and is electrically separated from the bit line 24 via the insulating layer 26. Referring to FIG. 10(b) as the sectional view taken along line B-B′, the word line 28 and the bit line 24 are eliminated.

After eliminating the photoresist 58, an interlayer insulating film 32 (including the silicon oxide film, for example) is formed on the word line 28 as shown in FIG. 11(a), and inside the groove 12 and on the insulating layer 26 as shown in FIG. 11(b). A plug metal 34 formed of such material as tungsten coupled to the bit line 24 is formed inside the interlayer insulating film 32. The wiring layer 36 is formed that is coupled to the plug metal 34 and extends on the bit line 24 in the same direction thereof. Thereafter, the wiring layer is further layered to complete production of the flash memory.

In one embodiment, the tunnel insulating film 14 and the trap layer 16 are formed to cover the inner surface of the groove 12 and the surface of the dummy layer 50 as shown in FIG. 6(b). Referring to FIG. 7(b), the trap layer 16 formed above the upper surface and at the sides of the dummy layer 50 is eliminated. Referring to FIG. 7(c), the top insulating film 18 is formed to cover the remaining trap layer 16 and the exposed tunnel insulating film 14. In the aforementioned manufacturing process, an end portion 48 of the trap layer 16 is covered with the top insulating film 18 as shown in FIG. 7(c). Accordingly, erosion of the trap layer 16 can be suppressed when the dummy layer 50 is eliminated.

Upon elimination of the trap layer 16, the bury layer 54 is formed in the groove 12 so as to expose the trap layer 16 at the sides of the dummy layer 50 as shown in FIG. 7(a). Thereafter, the trap layer 16 is eliminated while using the bury layer 54 as the mask. This makes it possible to selectively eliminate the trap layer 16 formed above the upper surface and the sides of the dummy layer 50.

Upon formation of the bury layer 54, the bury-layer-forming layer 53 is formed to fill the groove 12 and to cover the trap layer 16 as shown in FIG. 6(c). Then the bury-layer-forming layer 53 is eliminated such that the trap layer 16 at the side of the dummy layer 50 is exposed as shown in FIG. 7(a). Thus, the bury layer 54 may be formed in the groove 12 so as to expose the trap layer 16 at the sides of the dummy layer 50.

Referring to FIG. 8(a), the gate-electrode-forming layer 21 is formed to fill the groove 12 and to cover the top insulating film 18. Referring to FIG. 8(b), the gate-electrode-forming layer 21 is polished until it becomes flush with the dummy layer 50. Referring to FIG. 8(c), the dummy layer 50 is eliminated. The ion implantation is performed to the semiconductor substrate 10 while using the gate electrode 22 as the mask such that the bit line 24 is formed on the semiconductor substrate 10 between the grooves 12 where the dummy layer 50 has been eliminated as shown in FIG. 9(a). In the aforementioned process, the bit line 24 may be formed such that the upper surface thereof is lower than the upper surface of the gate electrode 22 by the amount corresponding to the film thickness of the dummy layer 50. The upper surface of the gate electrode 22 is kept exposed.

Referring to FIG. 9(b), the insulating layer 26 is formed on the bit line 24 so as to expose the upper surface of the gate electrode 22. Referring to FIG. 10(a), the word line 28 coupled to the gate electrode 22 is formed on the insulating layer 26. As a result, the word line 28 is electrically coupled with the gate electrode 22 and is electrically separated from the bit line 24 via the insulating layer 26.

According to this embodiment, each of the dummy layer 50 and the trap layer 16 is formed of the silicon nitride. However, any material may be used for forming the trap layer 16 so long as it is eroded upon etching of the dummy layer 50, thus providing the same effects as those derived from the previously described embodiments. For example, the same material may be used for forming both the dummy layer 50 and the trap layer 16.

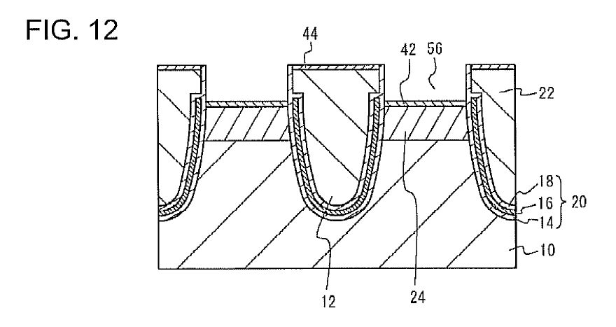

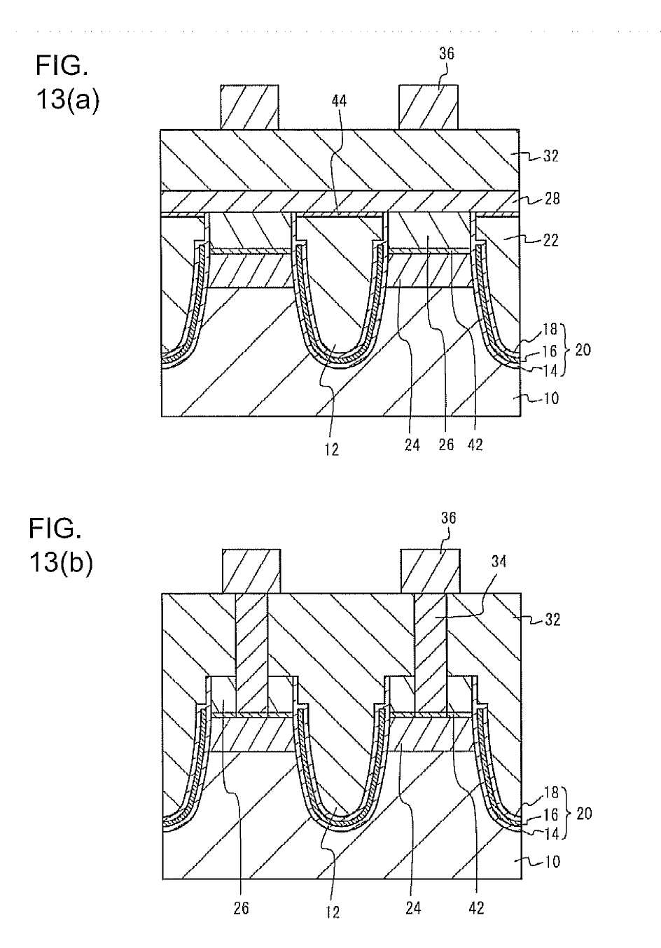

In a further embodiment, a metal silicide layer is formed on the bit line. Referring to FIGS. 12 to 13(b), a method for manufacturing a flash memory according to another embodiment will be described. FIG. 12 corresponds to a sectional view taken along lines A-A′ and B-B′ shown in FIG. 1. FIG. 13(a) corresponds to a sectional view taken along line A-A′ shown in FIG. 1, and FIG. 13(b) corresponds to a sectional view taken along line B-B′ shown in FIG. 1.

Referring to FIG. 12, after performing the process according to the embodiment shown in FIG. 9(a), a metal layer, for example, a cobalt layer or titanium layer (not shown) is formed on the inner surface of the recess portion 56 and above the upper surface of the gate electrode 22. Thereafter, the thermal processing is performed such that the metal layer on the bit line 24 and the gate electrode 22 is formed into the silicide to become metal silicide layers 42 and 44. The metal layer which is not formed into silicide is eliminated. Referring to FIGS. 13(a) and 13(b), the process according to the embodiment shown in FIGS. 9(b) to 11(b) is performed to complete production of the flash memory according to a further embodiment.

In one embodiment, after the dummy layer 50 is eliminated, the metal silicide layer 42 is formed on the bit line 24 between the grooves 12 where the dummy layer 50 has been eliminated. In this way, after forming the bit line 24, the metal silicide layer 42 may be continuously formed along the extending direction of the bit line 24. So the bit line resistance may be reduced. Simultaneously with the formation of the metal silicide layer 42, the metal silicide layer 44 may be formed on the gate electrode 22, thus reducing the gate resistance.

In one embodiment, the semiconductor devices described above may be implemented as Electrically Erasable Programmable Read Only Memory (EEPROM) devices, such as flash memory. Flash memory is nonvolatile and thus can maintain its contents even without power. However, flash memory is not identical to a standard EEPROM. Standard EEPROMs are differentiated from flash memory because they can be erased and reprogrammed on an individual byte or word basis while flash memory though capable of being programmed on a byte or word basis, is generally erased on a block basis. Although standard EEPROMs may appear to be more versatile, their functionality requires two transistors to hold one bit of data. In contrast, flash memory requires only one transistor to hold one bit of data, which results in a lower cost per bit. As flash memory costs far less than EEPROM, it has become the dominant technology wherever a significant amount of non-volatile, solid-state storage is needed.

Exemplary applications of flash memory include digital audio players, digital cameras, digital video recorders, and mobile phones. Flash memory is also used in USB flash drives, which are used for general storage and transfer of data between computers. Also, flash memory is gaining popularity in the gaming market, where low-cost fast-loading memory in the order of a few hundred megabytes is required, such as in game cartridges. Additionally, flash memory is applicable to cellular handsets, smartphones, personal digital assistants, set-top boxes, digital video recorders, networking and telecommunication equipments, printers, computer peripherals, automotive navigation devices, and gaming systems.

As flash memory is a type of non-volatile memory, it does not need power to maintain the information stored in the chip. In addition, flash memory offers fast read access times and better shock resistance than traditional hard disks. These characteristics explain the popularity of flash memory for applications such as storage on battery-powered devices (e.g., cellular phones, mobile phones, IP phones, wireless phones, etc.).

Flash memory stores information in an array of floating gate transistors, called “cells,” each of which traditionally stores one bit of information. However, newer flash memory devices can store more than 1 bit per cell. These newer flash memory devices double the intrinsic density of a Flash memory array by storing two physically distinct bits on opposite sides of a memory cell. Each bit serves as a binary bit of data (e.g., either 1 or 0) that is mapped directly to the memory array. Reading or programming one side of a memory cell occurs independently of whatever data is stored on the opposite side of the cell.

With regards to wireless markets, the newer flash memory devices have several key advantages, such as being capable of burst-mode access as fast as 80 MHz, page access times as fast as 25 ns, simultaneous read-write operation for combined code and data storage, and low standby power (e.g., 1 μA).

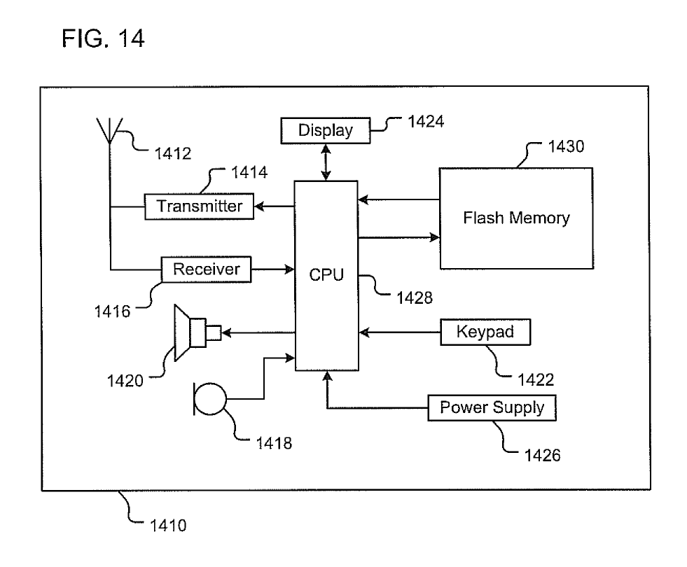

FIG. 14 shows a block diagram of an exemplary portable telephone 1410 (e.g., cell phone, cellular phone, mobile phone, internet protocol phone, wireless phone, etc.), upon which various embodiments of the invention can be implemented. The cell phone 1410 includes an antenna 1412 coupled to a transmitter 1414 and a receiver 1416, as well as a microphone 1418, a speaker 1420, a keypad 1422, and a display 1424. The cell phone 1410 also includes a power supply 1426 and a central processing unit (CPU) 1428, which may be an embedded controller, conventional microprocessor, or the like. In addition, the cell phone 1410 includes integrated, flash memory 1430. Flash memory 1430 can include a nonvolatile memory device with a shorter distance between the bit lines and higher storage capacity and density than those conventionally known. In various embodiments, the flash memory 1430 can be utilized with various devices, such as mobile phones, cellular phones, internet protocol phones, and/or wireless phones.

Flash memory comes in two primary varieties, NOR-type flash and NAND-type flash. While the general memory storage transistor is the same for all flash memory, it is the interconnection of the memory cells that differentiates the designs. In a conventional NOR-type flash memory, the memory cell transistors are coupled to the bit lines in a parallel configuration, while in a conventional NAND-type flash memory, the memory cell transistors are coupled to the bit lines in series. For this reason, NOR-type flash is sometimes referred to as “parallel flash” and NAND-type flash is referred to as “serial flash.”

Traditionally, portable phone (e.g., cell phone) CPUs have needed only a small amount of integrated NOR-type flash memory to operate. However, as portable phones (e.g., cell phone) have become more complex, offering more features and more services (e.g., voice service, text messaging, camera, ring tones, email, multimedia, mobile TV, MP3, location, productivity software, multiplayer games, calendar, and maps.), flash memory requirements have steadily increased. Thus, an improved flash memory will render a portable phone more competitive in the telecommunications market.

Also, as mentioned above, flash memory is applicable to a variety of devices other than portable phones. For instance, flash memory can be utilized in personal digital assistants, set-top boxes, digital video recorders, networking and telecommunication equipments, printers, computer peripherals, automotive navigation devices, and gaming systems.

It is noted that the components (e.g., 1412, 1414, 1416, 1422, 1428, 1430, etc.) of portable telephone 1410 can be coupled to each other in a wide variety of ways. For example, in an embodiment, the antenna 1412 can be coupled to transmitter 1414 and receiver 1416. Additionally, the transmitter 1414, receiver 1416, speaker 1420, microphone 1418, power supply 1426, keypad 1422, flash memory 1430 and display 1424 can each be coupled to the processor (CPU) 1428. It is pointed out that in various embodiments, the components of portable telephone 1410 can be coupled to each other via, but are not limited to, one or more communication buses, one or more data buses, one or more wireless communication technologies, one or more wired communication technologies, or any combination thereof.

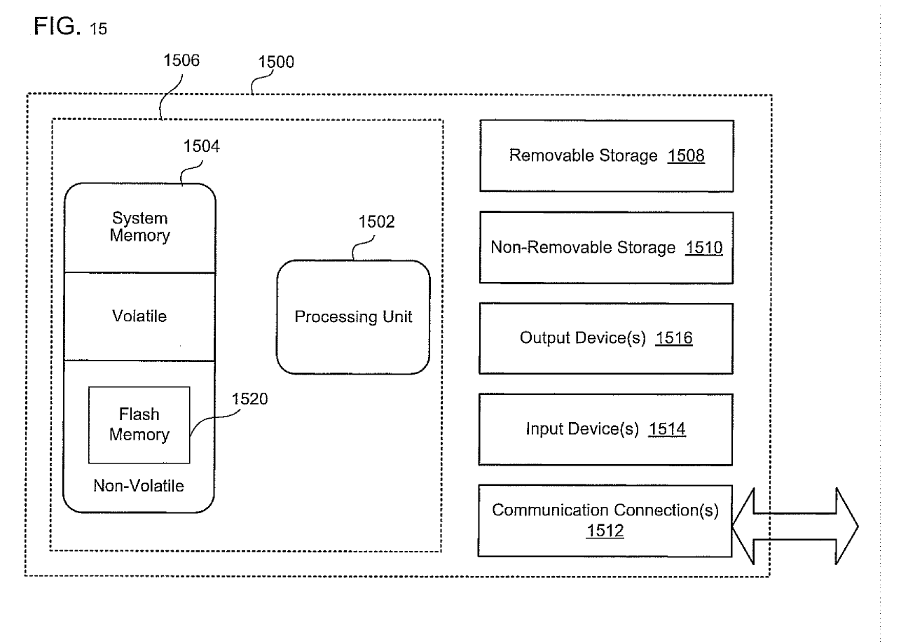

FIG. 15 illustrates a block diagram of an exemplary computing device 1500, upon which various embodiments of the invention can be implemented. Although computing device 1500 is shown and described in FIG. 15 as having certain numbers and types of elements, the embodiments are not necessarily limited to the exemplary implementation. That is, computing device 1500 can include elements other than those shown, and can include more than one of the elements that are shown. For example, computing device 1500 can include a greater number of processing units than the one (processing unit 1502) shown. In an embodiment, computing device 1500 can include additional components not shown in FIG. 15.

Also, it is appreciated that the computing device 1500 can be a variety of things. For example, computing device 1500 may be, but is not limited to, a personal desktop computer, a portable notebook computer, a personal digital assistant (PDA), and a gaming system. Flash memory is especially useful with small-form-factor computing devices such as personal data assistants (PDAs) and portable gaming devices. Flash memory offers several advantages. In one example, flash memory is able to offer fast read access times while at the same time being able to withstand shocks and bumps better than standard hard disks. This is important as small computing devices are often moved around and encounter frequent physical impacts. Also, flash memory is more able than other types of memory to withstand intense physical pressure and/or heat. Thus, portable computing devices are able to be used in a greater range of environmental variables.

Computing device 1500 can include at least one processing unit 1502 and memory 1504. Depending on the exact configuration and type of computing device, memory 1504 may be volatile (such as RAM), non-volatile (such as ROM, flash memory, etc.) or some combination of the two. This most basic configuration of computing device 1500 is illustrated in FIG. 15 by line 1506. Additionally, device 1500 may also have additional features/functionality. For example, device 1500 may also include additional storage (removable and/or non-removable) including, but not limited to, magnetic or optical disks or tape. In one example, in the context of a gaming system, the removable storage could be a game cartridge receiving component utilized to receive different game cartridges. In another example, in the context of a Digital Versatile Disc (DVD) recorder, the removable storage is a DVD receiving component utilized to receive and read DVDs. Such additional storage is illustrated in FIG. 15 by removable storage 1508 and non-removable storage 1510. Computer storage media includes volatile and nonvolatile, removable and non-removable media implemented in any method or technology for storage of information such as computer readable instructions, data structures, program modules or other data. Memory 1504, removable storage 1508 and non-removable storage 1510 are all examples of computer storage media. Computer storage media includes, but is not limited to, RAM, ROM, EEPROM, flash memory 1520 or other memory technology, CD-ROM, digital video disks (DVD) or other optical storage, magnetic cassettes, magnetic tape, magnetic disk storage or other magnetic storage devices, or any other medium which can be used to store the desired information and which can accessed by device 1500. Any such computer storage media may be part of device 1500.

Device 1500 may also contain communications connection(s) or coupling(s) 1512 that allow the device to communicate with other devices. Communications connection(s) 1512 is an example of communication media. Communication media typically embodies computer readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection or coupling, and wireless media such as acoustic, radio frequency (RF), infrared and other wireless media. The term computer readable media as used herein includes both storage media and communication media.

It is noted that the components (e.g., 1502, 1504, 1510, 1520, etc.) of computing device 1500 can be coupled to each other in a wide variety of ways. For example in various embodiments, the components of computing device 1500 can be coupled to each other via, but are not limited to, one or more communication buses, one or more data buses, one or more wireless communication technologies, one or more wired communication technologies, or any combination thereof.

Device 1500 may also have input device(s) 1514 such as keyboard, mouse, pen, voice input device, game input device (e.g., a joy stick, a game control pad, and/or other types of game input device), touch input device, etc. Output device(s) 1516 such as a display (e.g., a computer monitor and/or a projection system), speakers, printer, network peripherals, etc., may also be included. All these devices are well known in the art and need not be discussed at length here.

Aside from mobile phones and portable computing devices, flash memory is also widely used in portable multimedia devices, such as portable music players. As users would desire a portable multimedia device to have as large a storage capacity as possible, an increase in memory density would be advantageous.

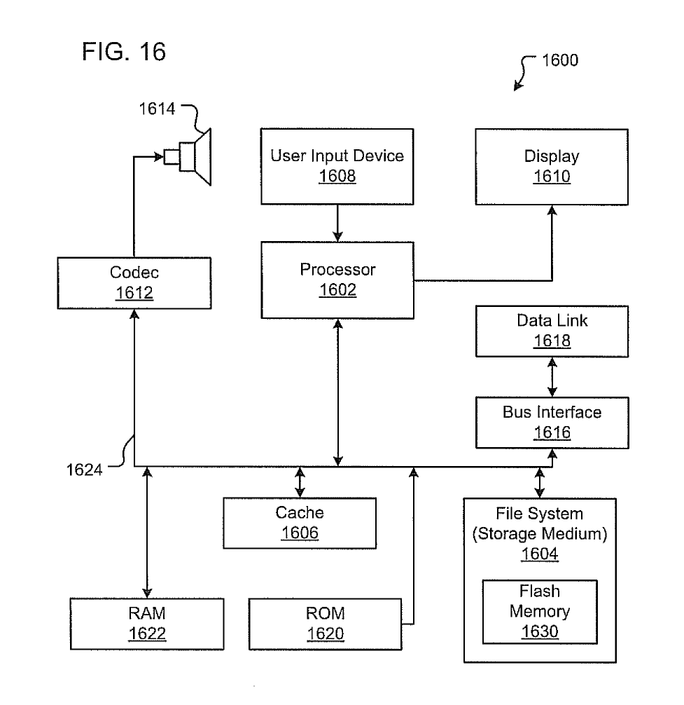

FIG. 16 shows an exemplary portable multimedia device, or media player, 1600 in accordance with an embodiment of the invention. The media player 1600 includes a processor 1602 that pertains to a microprocessor or controller for controlling the overall operation of the media player 1600. The media player 1600 stores media data pertaining to media assets in a file system 1604 and a cache 1606. The file system 1604 is, typically, a storage medium or a plurality of storage media, such as disks, memory cells, and the like. The file system 1604 typically provides high capacity storage capability for the media player 1600. Also, file system 1604 includes flash memory 1630. In the present embodiment, Flash memory 1630 can include a nonvolatile memory device with a shorter distance between the bit lines and higher storage capacity and density than those conventionally known. In various embodiments, the flash memory 1630 can be utilized with various devices, such as personal digital assistants, set-top boxes, digital video recorders, networking and telecommunication equipments, printers, computer peripherals, automotive navigation devices, gaming systems, mobile phones, cellular phones, internet protocol phones, and/or wireless phones. However, since the access time to the file system 1604 is relatively slow, the media player 1600 can also include a cache 1606. The cache 1606 is, for example, Random-Access Memory (RAM) provided by semiconductor memory. The relative access time to the cache 1606 is substantially shorter than for the file system 1604. However, the cache 1606 does not have the large storage capacity of the file system 1604. Further, the file system 1604, when active, consumes more power than does the cache 1606. The power consumption is particularly important when the media player 1600 is a portable media player that is powered by a battery (not shown). The media player 1600 also includes a RAM 1622 and a Read-Only Memory (ROM) 1620. The ROM 1620 can store programs, utilities or processes to be executed in a non-volatile manner. The RAM 1622 provides volatile data storage, such as for the cache 1606.

The media player 1600 also includes a user input device 1608 that allows a user of the media player 1600 to interact with the media player 1600. For example, the user input device 1608 can take a variety of forms, such as a button, keypad, dial, etc. Still further, the media player 1600 includes a display 1610 (screen display) that can be controlled by the processor 1602 to display information to the user. A data bus 1624 can facilitate data transfer between at least the file system 1604, the cache 1606, the processor 1602, and the CODEC 1612. The media player 1600 also includes a bus interface 1616 that couples to a data link 1618. The data link 1618 allows the media player 1600 to couple to a host computer.

In one embodiment, the media player 1600 serves to store a plurality of media assets (e.g., songs, photos, video, etc.) in the file system 1604. When a user desires to have the media player play/display a particular media item, a list of available media assets is displayed on the display 1610. Then, using the user input device 1608, a user can select one of the available media assets. The processor 1602, upon receiving a selection of a particular media item, supplies the media data (e.g., audio file, graphic file, video file, etc.) for the particular media item to a coder/decoder (CODEC) 1610. The CODEC 1610 then produces analog output signals for a speaker 1614 or a display 1610. The speaker 1614 can be a speaker internal to the media player 1600 or external to the media player 1600. For example, headphones or earphones that couple to the media player 1600 would be considered an external speaker.

In a particular embodiment, the available media assets are arranged in a hierarchical manner based upon a selected number and type of groupings appropriate to the available media assets. For example, in the case where the media player 1600 is an MP3-type media player, the available media assets take the form of MP3 files (each of which corresponds to a digitally encoded song or other audio rendition) stored at least in part in the file system 1604. The available media assets (or in this case, songs) can be grouped in any manner deemed appropriate. In one arrangement, the songs can be arranged hierarchically as a list of music genres at a first level, a list of artists associated with each genre at a second level, a list of albums for each artist listed in the second level at a third level, while at a fourth level a list of songs for each album listed in the third level, and so on.

It is noted that the components (e.g., 1602, 1604, 1620, 1630, etc.) of media player 1600 can be coupled to each other in a wide variety of ways. For example, in an embodiment, the codec 1622, RAM 1622, ROM 1620, cache 1606, processor 1602, storage medium 1604, and bus interface 1616 can be coupled to data bus 1624. Furthermore, the data link 1618 can be coupled to the bus interface 1616. The user input device 1608 and the display 1610 can be coupled to the processor 1602 while the speaker 1614 can be coupled to the codec 1612. It is pointed out that in various embodiments, the components of media player 1600 can be coupled to each other via, but are not limited to, one or more communication buses, one or more data buses, one or more wireless communication technologies, one or more wired communication technologies, or any combination thereof.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A system, comprising:
a processor;
a cache;
a user input component; and
a flash memory, wherein the flash memory comprises:
a substrate;
a dummy layer formed on the substrate;
a groove formed in the substrate, the groove being formed while using the dummy layer as a mask;
a tunnel insulating film and a trap layer disposed on an inner surface of the groove and the dummy layer;
a top insulating film covering portions of the trap layer and tunnel insulating film,
wherein the trap layer is covered by the top insulating film to suppress erosion of the trap layer.

2. The system according to claim 1, wherein portions of the trap layer not covered by the top insulating film are eliminated during fabrication of the flash memory.

3. The system according to claim 2, wherein the portions of the trap layer are eliminated by forming a bury layer in the groove to expose the trap layer at the sides of the dummy layer and eliminating the trap layer while using the bury layer as a mask.

4. The system according to claim 3, wherein forming a bury layer during the fabricating of the flash memory comprises:
forming a layer to be formed as the bury layer to fill the groove and to cover the trap layer; and
eliminating the layer to be formed as the bury layer to expose at least the trap layer at the sides of the dummy layer.

5. The system according to claim 1, wherein the dummy layer of the flash memory is eliminated.

6. The system according to claim 5, wherein the flash memory further comprises a bit line disposed in the substrate where the dummy layer has been eliminated.

7. The system according to claim 6, wherein the flash memory further comprises a gate electrode formed in a groove in the top insulating film.

8. The system according to claim 7, wherein the bit line is disposed in the substrate by performing an ion implantation in the semiconductor substrate while using the gate electrode as a mask.

9. The according to claim 8, wherein the gate electrode is formed in the flash memory by filling the groove and covering the top insulating film to form a layer to be formed as the gate electrode, and polishing the layer to be formed as the gate electrode to be flush with the dummy layer.

10. The system according to claim 8, wherein the flash memory further comprises an insulating layer disposed on the bit line to expose an upper surface of the gate electrode.

11. The system according to claim 10, wherein the flash memory further comprises a word line coupled to the gate electrode and intersecting with the bit line.

12. The system according to claim 6, further comprising a metal silicide layer disposed on the bit line between the grooves where the dummy layer has been eliminated.

13. The system according to claim 1, wherein the dummy layer and the trap layer are formed from a same material.

14. The system according to claim 1, wherein a silicon nitride is used for forming the dummy layer and the trap layer.

15. The system according to claim 1 wherein the system is a portable media player.

16. The system according to claim 1 wherein the system is a cellular telephone.

17. The system according to claim 1 wherein the system is a computing device.

18. The system according to claim 17 wherein the computing device is a desktop computing device.

19. The system according to claim 17 wherein the computing device is a laptop or mobile computing device.

20. The system according to claim 1 wherein the system is a video game console device.
